(19) United States
(12) Patent Application Publication
(10) Pub. No.: US 2013/0255764 A1
(43) Pub. Date: Oct. 3, 2013

(54) STACKED ELECTRODE, STACKED ELECTRODE PRODUCTION METHOD, AND PHOTOELECTRIC CONVERSION DEVICE

(71) Applicant: KABUSHIKI KAISHA TOSHIBA, Tokyo (JP)

(72) Inventors: Katsuyuki Naito, Tokyo (JP); Eishi Tsutsumi, Kanagawa (JP); Norihiro Yoshinaga, Kanagawa (JP); Yoshihiro Akasaka, Kanagawa (JP)

(73) Assignee: KABUSHIKI KAISHA TOSHIBA, Tokyo (JP)

(21) Appl. No.: 13/771,717

(22) Filed: Feb. 20, 2013

(30) Foreign Application Priority Data
Mar. 30, 2012 (JP) 2012-081927

(51) Int. Cl. H01L 31/0224; H05K 1/02

(52) U.S. Cl. CPC H01L 31/022425; H05K 1/0298; Y10S 977/755
USPC 136/256; 427/74; 174/253; 977/755

(57) ABSTRACT

A stacked electrode of an embodiment includes: a multi-layered graphene film and a metal wiring formed thereon, wherein the metal wiring contains randomly oriented metal nanowires, the multi-layered graphene film contains a laminate of graphene sheets, the graphene sheets each contain an aggregate of graphene plates, and the graphene plates have an average area of (A+B)² nm² or more, wherein A (nm) represents the average diameter of the metal nanowires, B (nm) satisfies the equation (1) of B²/(A+B)²=(1−X), and X represents the ratio of the area of the metal nanowires projected in the stacking direction of the stacked electrode.

### CROSS-REFERENCE TO RELATED APPLICATION

This application is based upon and claims the benefit of priority from Japanese Patent Applications No. 2012-081927, filed on Mar. 30, 2012; the entire contents of which are incorporated herein by reference.

### FIELD

Embodiments described herein relate generally to a stacked electrode, a stacked electrode production method, and a photoelectric conversion device.

### BACKGROUND

Various developments have been made on conductors containing carbon materials (such as carbon fibers, carbon nanotubes, and graphenes) and electrical devices using the conductors including photoelectric conversion devices (such as solar cells, organic EL devices, and optical sensors).

The carbon material can be used to greatly reduce the usage of a rare metal or the like. The carbon material is excellent in flexibility, mechanical strength, and chemical stability. The carbon material has a relatively high conductivity and exhibits a high resistance in intermolecular conduction. A large-area transparent electrode containing the carbon material has a higher electrical resistance as compared with those containing an indium tin oxide (ITO) film having the same light transmittance. In addition, the carbon material exhibits a higher electrical resistance in a long-distance electrical wire or the like as compared with conductive metal materials containing copper or the like. Therefore, composites of the carbon material and a particle or wire of a metal or semiconductor have been studied in view of improving the conductivity.

### BRIEF DESCRIPTION OF THE DRAWINGS

FIG. 1 is a conceptual cross-sectional view of a stacked electrode according to an embodiment;

FIG. 2 is an AFM image of a graphene sheet according to the embodiment;

FIG. 3 is a conceptual top view of the stacked electrode of the embodiment;

FIG. 4 is a conceptual view of the stacked electrode of the embodiment; and

FIG. 5 is a conceptual view of a photoelectric conversion device according to an embodiment.

### DETAILED DESCRIPTION

A stacked electrode of an embodiment includes: a multi-layered graphene film and a metal wiring formed thereon, wherein the metal wiring contains randomly oriented metal nanowires, the multi-layered graphene film contains a laminate of graphene sheets, the graphene sheets each contain an aggregate of graphene plates, and the graphene plates have an average area of (A+B)² nm² or more, wherein A (nm) represents the average diameter of the metal nanowires, B (nm) satisfies the equation (1) of B²/(A+B)²=(1−X), and X represents the ratio of the area of the metal nanowires projected in the stacking direction of the stacked electrode.

A method for producing a stacked electrode of an embodiment includes: preparing a multi-layered graphene film; applying a dispersion liquid of a metal nanowire onto the multi-layered graphene film, and removing a solvent from the applied dispersion liquid.

A photoelectric conversion device of an embodiment includes: at least two electrodes and a photoelectric conversion layer interposed therebetween, wherein at least one of the electrodes is a stacked electrode containing a multi-layered graphene film and a metal wiring formed thereon, the metal wiring contains randomly oriented metal nanowires, the multi-layered graphene film contains a laminate of graphene sheets, the graphene sheets each contain an aggregate of graphene plates, and the graphene plates have an average area of (A+B)² nm² or more, wherein A (nm) represents the average diameter of the metal nanowires, B (nm) satisfies the equation (1) of B²/(A+B)²=(1−X), and X represents the ratio of the area of the metal nanowires projected in the stacking direction of the stacked electrode.

Embodiments of the invention will be described below with reference to the drawings.

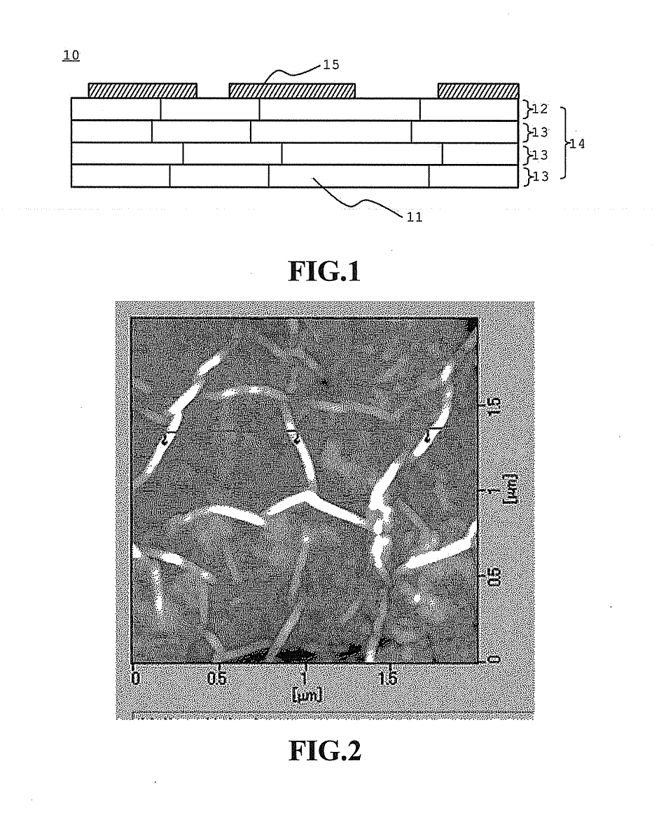

As shown in the conceptual cross-sectional structure example view of FIG. 1, a stacked electrode 10 according to the embodiment has a multi-layered graphene film 14 and a metal wiring 15 formed thereon. A functional substrate of a photoelectric conversion device, a display device, or the like may be disposed below the stacked electrode 10.

The multi-layered graphene film 14 contains a laminate of graphene sheets 12 and 13, which each contain an aggregate of graphene plates 11. The uppermost graphene sheet 12 is in direct contact with the metal wiring 15, and the graphene sheets 13 disposed below the graphene sheet 12 are not in direct contact with the metal wiring 15.

The graphene plate 11 contains a high-crystallinity graphene and has a high electrical conductivity. When the graphene plate 11 is composed of a defect-free graphene, the graphene plate 11 has a conductivity of 10⁶ S/cm in the film plane direction. The graphene plate 11 may have a size of 0.001 to 100 μm².

FIG. 2 is an AFM image example of the graphene sheet containing the aggregate of the graphene plates prepared from a graphene oxide. As is clear from FIG. 2, the graphene sheet contains the aggregate of the graphene plates 11, which each have a crystal grain boundary and a diameter of approximately 500 nm. In this example, some of the graphene plates 11 have a bent structure. The graphene plates 11 partially overlap with each other though the overlap cannot be observed in the shown surface. Even in a case where the graphene sheet is prepared by a CVD process, the resultant sheet contains the aggregate of the graphene plates 11 in the same manner as that prepared from the graphene oxide. The size and shape of the graphene plate 11 depend on the preparation conditions.

Though the conductivity of the graphene plate 11 may be lowered by a defect formed therein, the graphene plate 11 generally has an electrical conductivity sufficient for use in a transparent conductive film. Meanwhile, the graphene plates 11 exhibit a resistance in the conduction between each other. The graphene sheet prepared by the CVD process contains the aggregate of small graphene plates and has a conductivity of approximately 10² to 10⁴ S/cm in the film plane direction. The graphene sheet prepared by reducing and heating the graphene oxide contains the aggregate of graphene plates and has a conductivity of approximately 10¹ to 10² S/cm in the film plane direction. Therefore, the graphene sheet prepared using the CVD process or the graphene oxide cannot singly exhibit an electrical conductivity sufficient for use in a transparent electrode.

The metal wiring 15 has a high electrical conductivity. When the metal wiring 15 is formed on the graphene sheet 12, the stacked electrode 10 can have a sufficient conductivity in the film plane direction. Such a multi-layered graphene structure is known to have a relatively high resistance between graphene layers in the film thickness direction. When the multi-layered graphene film 14 has a remarkably small thickness (a small number of graphene layers), its resistance is not very high in the film thickness direction. As the number of the graphene layers in the multi-layered graphene film 14 increases, the light transmittance is lowered. Thus, it is undesirable that the number of the graphene sheets 13 is excessively increased. When the multi-layered graphene film 14 has a thickness of 5 nm or less, the stacked electrode of the embodiment has excellent electrical conductivity and transmittance and thereby can be used as a transparent electrode for a display device, a solar cell, or the like. The thickness is further preferably 0.6 to 2 nm. When the thickness is 2 nm or less, the multi-layered graphene film 14 can have an increased transparency. When the thickness is less than 0.6 nm, the multi-layered graphene film 14 has a single-layer portion and a bi-layer portion, and it is difficult to form a uniform structure.

The graphene plate 11 of the embodiment may contain an unsubstituted or substituted graphene. It is preferred that carbon atoms in the graphene plate are partially substituted by nitrogen (N) or boron (B) atoms for the following reasons. Such a substituent atom can be coordinated with a metal in a wiring material to strengthen the connection between the graphene and the metal material. Furthermore, the substituent atom can facilitate the electron transfer to lower the interface electrical resistance between the graphene plate (the graphene sheet) and the wiring material. In addition, the substituent atom has an effect of preventing oxidation of the easily oxidizable wiring material. When the carbon atoms are partially substituted by the nitrogen atoms, the resultant graphene plate has a work function lower than that of an unsubstituted graphene plate and therefore can be suitably used in a negative electrode. When the carbon atoms are partially substituted by the boron atoms, the resultant graphene plate has a work function higher than that of an unsubstituted graphene plate and therefore can be suitably used in a positive electrode.

When the carbon atoms in the graphene plate are partially substituted by the nitrogen atoms, the number ratio of the nitrogen atoms to the carbon atoms is preferably 1/1000 to 1/5. The substituent nitrogen atoms may be in the form of pyridine, pyrrole/pyridone, N-oxide, quaternary nitrogen, or the like.

When the carbon atoms in the graphene plate are partially substituted by the boron atoms, the number ratio of the boron atoms to the carbon atoms is preferably 1/1000 to 1/5. The substituent boron atoms may be in the form of boron-oxygen, boron-nitrogen, boron-substituted graphite skeleton, boron-boron, or the like.

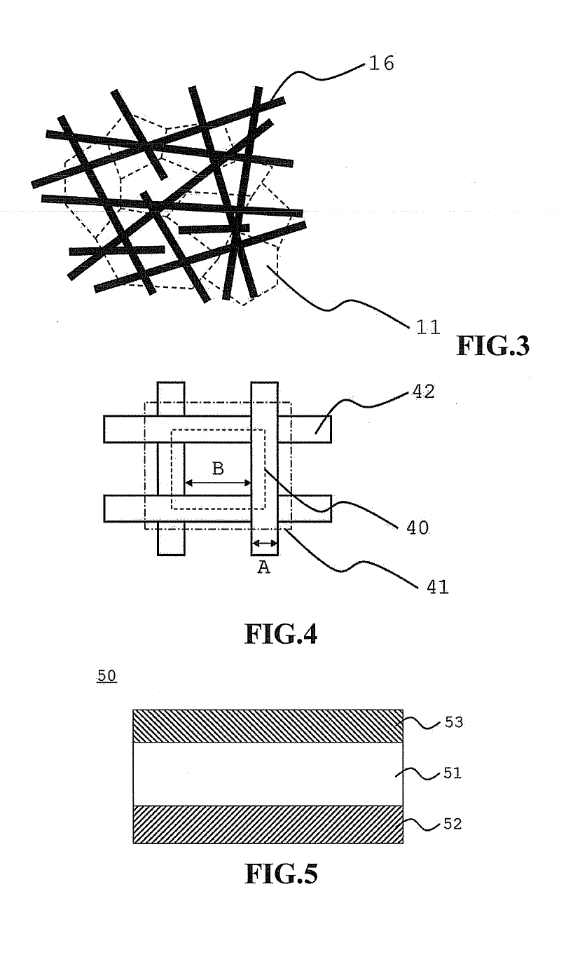

As shown in the conceptual top view of FIG. 3, the metal wiring 15 of the embodiment is formed on the graphene plates 11. The metal wiring 15 is discontinuously provided on the graphene sheet 12 in FIG. 1. The metal wiring 15 contains randomly oriented metal nanowires 16. The metal wiring 15 may be formed on a surface of the graphene sheet 12 at an appropriate ratio in view of the wiring density, transmittance, and electrical conductivity. The metal wiring 15 may further contain a nanowire protecting polymer or a conductive aid as long as the transmittance of the metal wiring 15 is not adversely affected by the agent. The randomly oriented metal nanowires 16 have a mesh structure and an excellent light transmittance. The metal nanowires 16 are electrically connected to the graphene plates 11 in the graphene sheet 12. The metal nanowires 16 partially overlap with each other to form a metal nanowire layer.

The metal nanowires 16 preferably have a diameter of 20 nm or more to obtain a desired length. In view of the electrical conductivity and the mesh structure, the average diameter of the metal nanowires 16 is preferably 20 to 200 nm, more preferably 30 to 150 nm, further preferably 50 to 120 nm. For example, the diameter of the metal nanowires 16 can be measured by observation using a scanning electron microscope (SEM), a transmission electron microscope (TEM), or an atomic force microscope (AFM).

The average length of the metal nanowires 16 may be appropriately selected in view of the conductivity and transparency of the resultant electrode. Specifically, the average length is preferably at least 1 μm in view of the conductivity, and is preferably at most 100 μm to avoid transparency deterioration by an aggregation of the metal nanowires 16. The optimum length of the metal nanowires 16 depends on the diameter thereof. The ratio of the length to the diameter (the length/diameter ratio) of the metal nanowires 16 may be approximately 100 to 1000.

The thickness of the metal nanowire layer may be appropriately selected depending on the diameter of the metal nanowires 16, the number of the overlaps, and the like. Specifically, the metal nanowire layer has a thickness of approximately 30 to 300 nm.

The metal nanowires 16 preferably contain silver, gold, or copper. Such a metal has a low electrical resistance of approximately 2×10⁻⁸ Ω/m or less and a relatively high chemical stability, and thereby is preferably used in this embodiment. When the metal nanowires 16 contain 60% by mass or more of this metal, an alloy of palladium, indium, bismuth, zinc, nickel, aluminum, or the like may be used in the metal nanowires 16. The metal nanowires 16 may contain an alloy of silver, gold, or copper.

When one graphene plate in the uppermost graphene sheet is not connected to the metal nanowire, electrons cannot be efficiently transferred to or from the lower graphene plate, so that a function of a device using the stacked electrode is deteriorated. It is preferred that the following condition is satisfied to connect a larger number of the graphene plates 11 in the graphene sheet 12 with the metal nanowires 16.

FIG. 4 is a conceptual view of the relation between the graphene plate size and a mesh size of the metal nanowire layer in the stacked electrode of this embodiment. In the conceptual view of FIG. 4, a graphene plate 41 and metal nanowires 42 having a diameter of A (nm) are shown. The metal nanowires 42 are arranged at regular intervals, are perpendicularly crossed, and form a square 40 as a unit lattice. When the opening in the unit lattice has a side length of B (nm), the unit lattice has an area of (A+B)² nm².

Thus, when X represents the area ratio of the metal nanowires, the equation (1) of B²/(A+B)²=(1−X) is satisfied, the overlapped areas being not redundantly calculated.

In order that the graphene plate 41 is connected to the metal nanowires 42, the graphene plate 41 has to have a calculated average area of (A+B)² nm² or more. When this condition is satisfied, a larger number of the graphene plates can be electrically connected with the metal nanowires, and theoretically all the graphene plates can be electrically connected with the metal nanowires. When a larger number of the graphene plates are connected with the metal wiring, the stacked electrode can be obtained with a low resistance and a high transmittance. The average area of the graphene plates is preferably 2(A+B)² nm² or more, more preferably 3(A+B)² nm² or more. A very thin metal film may be inserted between the graphene layer and the metal nanowire to improve the conductivity and contact. The thickness of the film is less than 10 nm, and preferably less than 5 nm to get a good transmittance. Transparent conducting materials such as ITO nanoparticles and conducting polymer may be included in the metal nanowire layer to improve the conductivity.

It is preferred that the graphene plates have a further large average area. However, such large graphene plates cannot be easily prepared in some cases. Furthermore, when the graphene sheet is prepared from the dispersion of the graphene oxide or the like, uniform dispersion and sheet formation cannot be easily carried out due to the aggregation of the graphene oxide or the like. The ratio X is preferably 0.5 or less, more preferably 0.3 or less, in view of the light transmittance. However, when the ratio X is less than 0.05, the resultant electrode disadvantageously has an increased surface resistance.

The electrode can be optimized by appropriately selecting the preparation conditions of the graphene plates and the metal nanowires under the above-described model condition. For example, in the case of using the metal nanowires having an average diameter of 20 nm, the (A+B)² value is 1.6×10⁴ nm² (1.6×10⁻² μm²) when the ratio X is 0.05, and the (A+B)² value is 1.7×10³ nm² when the ratio X is 0.5. Furthermore, in the case of using the metal nanowires having an average diameter of 200 nm, the (A+B)² value is 1.2×10⁶ nm² when the ratio X is 0.05, and the (A+B)² value is 1.6×10⁵ nm² when the ratio X is 0.5. The sizes of the graphene plates and the metal nanowires may be appropriately selected in accordance with the intended use in this manner.

A preferred area of the graphene plates can be practically obtained from the area ratio and the average diameter of the metal nanowires in the wiring in the same manner as the model structure of FIG. 4. First, an image of the graphene plates of FIG. 1 is taken in the vertical direction using a scanning electron microscope, a transmission electron microscope, or an atomic force microscope. The image preferably includes ten or more observable graphene plates. It is preferred that a central region of the measurement subject sample is observed using the microscope. The diameters of the metal nanowires in the image are measured to obtain the average diameter A. The ratio X of the metal nanowires in the image, the ratio of (the area of the metal nanowires)/(the observed area), is calculated. The ratio X is obtained in a square (the observed area), and the side length of the square is 30 to 50 times larger than the calculated average diameter of the metal nanowires. In the measurement of the metal nanowire area, the areas of the overlapped portions in the metal nanowires are not redundantly added. Then, the B value is obtained using the values X and A in the equation (1) of B²/(A+B)²=(1−X).

Thus, the graphene plates preferably has an average area of (A+B)² or more.

The average area of the graphene plates may be calculated from the areas of five graphene plates randomly selected from the image. When the median of the areas of the graphene plates measured in the image is different by 30% or more from the calculated average area of the graphene plates, it is preferable to review the selection of the graphene plates for calculating the average area. In the measurement of the graphene plate area, the areas of the overlapped portions in the graphene plates are not redundantly added.

The stacked electrode 10 of the embodiment is preferably coated with a near-infrared transparent resin. The multi-layered graphene film 14 and the metal wiring 15 have a high near-infrared transparency. Thus, when the stacked electrode 10 is coated with the near-infrared transparent resin, the resultant near-infrared transparent conductive film can be used for producing a solar cell or optical sensor capable of efficiently utilize a near-infrared light. The near-infrared transparent resin is preferably such an amorphous resin that a hydrogen atom on its main carbon chain is substituted by a fluorine atom. For example, the near-infrared transparent resin may be CYTOP (available from Asahi Glass Co., Ltd.).

A method for producing the stacked electrode of the embodiment will be described below.

The method for producing the stacked electrode 10 of the embodiment shown in the conceptual view of FIG. 1 contains preparing the multi-layered graphene film 14, applying a dispersion liquid of the metal nanowires 16 onto the multi-layered graphene film 14, and removing a dispersion medium from the applied dispersion liquid to form the metal wiring 15. The metal wiring 15 may be formed by applying the dispersion liquid of the metal nanowires 16 to a support such as a transparent substrate and by transferring the applied metal nanowires 16 onto the multi-layered graphene film 14. Alternatively, the metal wiring 15 may be formed on a single-layer graphene, and then the multi-layered graphene film 14 may be formed from the single-layer graphene.

Each single-layer graphene in the multi-layered graphene film 14 may be prepared by applying and reducing a graphene oxide. Thus, the stacked electrode can be produced without vacuum processes with a large area and a low cost, and can be suitably used for a solar cell or the like.

In another method for preparing the single-layer graphene in the multi-layered graphene film 14, a graphene layer is preferably prepared by a CVD process using a carbon source. The graphene layer prepared by the process has a reduced number of defects, and therefore can be suitably used for a high-definition display or the like.

For example, an unsubstituted single-layer graphene may be prepared by a CVD process using a mixed reactant gas containing methane, hydrogen, and argon on a catalyst underlayer of a Cu foil. It is preferred that a surface of the Cu foil is annealed by a laser irradiation heating treatment before the CVD process to increase the crystal grain size.

For example, a single-layer graphene, in which the carbon atoms are partially substituted by nitrogen atoms, may be prepared by a chemical vapor deposition (CVD) process using a mixed reactant gas containing ammonia, methane, hydrogen, and argon on a catalyst underlayer of a Cu foil. The resultant graphene may be subjected to a heating treatment in a mixed flow of ammonia and argon and then cooled in an argon flow.

In the preparation of the partially nitrogen-substituted single-layer graphene, a low-molecular nitrogen compound such as pyridine, methylamine, ethylenediamine, or urea may be used as a material for the CVD process instead of the ammonia gas, and ethylene, acetylene, methanol, ethanol, or the like may be used as the carbon source instead of the methane.

The multi-layered graphene film 14 may be prepared by transferring the single-phase graphene onto a transfer film and by stacking the single-phase graphenes. Thus, the transfer film is press-bonded to the prepared single-layer graphene, and the single-layer graphene is peeled off from the underlayer, for example, by immersing in an ammonia-alkaline cupric chloride etchant. Then, the single-layer graphene is transferred from the transfer film to a desired substrate. The multi-layered graphene film 14 can be prepared by repeating these steps to stack the single-layer graphenes.

The graphene used in the transferring step may be formed not by the CVD process but by using the graphene oxide. Thus, the graphene may be formed by spin-coating a metal such as Cu with a thin film of a water dispersion liquid containing the graphene oxide and by subjecting the thin film to a heating nitrogen substitution treatment in an atmosphere of a mixture of ammonia, hydrogen, and argon. The graphene used in the transferring step may be formed by subjecting a thin graphene oxide film to a hydrazine treatment under heating and by drying the treated film. The graphene may be formed by treating a thin unsubstituted graphene film with a nitrogen plasma. Alternatively, the graphene used in the transferring step may be formed by applying a microwave onto Cu, thereby generating a plasma for preparing a thin nitrogen-substituted graphene film, in an atmosphere of a mixture of ammonia, methane, hydrogen, and argon. In addition, the graphene may be electrochemically reduced in a supporting electrolyte solution. The supporting electrolyte is most preferably a quaternary ammonium salt or a quaternary phosphonium salt. In this case, the graphene is doped with a reductant (an electron) and a counter cation (a quaternary ammonium ion or a quaternary phosphonium ion).

A partially boron-substituted single-layer graphene can be prepared in the same manner using a mixed reactant gas containing diborane, methane, hydrogen, and argon.

The layer number of the multi-layered graphene film 14 can be measured using a high-resolution TEM (transmission electron microscope). The area of the graphene plate 11 can be measured by observing the grain boundary using a TEM, an SEM, an AFM, or a low energy electron microscope (LEEM)

For example, the metal wiring 15 of the embodiment may be formed on the multi-layered graphene film 14 or a transparent substrate from a dispersion liquid containing the metal nanowires 16.

The dispersion liquid of the metal nanowires 16 may be applied to a surface of the multi-layered graphene film 14 or the transparent substrate to form an applied film by a spin coating method, a bar coating method, an ink-jet printing method, or the like. For example, a network structure of the metal nanowires 16 may be formed by drying the applied film in a nitrogen or argon flow at approximately 50° C. to 100° C. for about 0.5 to 2 hours to remove the dispersion medium. The thickness of the network structure can be controlled at a desired value by repeating the steps of applying and drying the dispersion liquid.

The multi-layered graphene film 14 has a high tolerance to various solvents, and is not degraded by the dispersion medium for the metal nanowires 16. The metal wiring 15 can be bonded to the multi-layered graphene film 14 easily, uniformly, and rigidly by spreading the metal nanowires 16 directly on the multi-layered graphene film 14.

In view of stably dispersing the metal nanowires 16 in the dispersion medium, the metal nanowires 16 preferably have a diameter of 200 nm or less. When the metal nanowires 16 have a diameter of more than 200 nm, the dispersion of the metal nanowires 16 in the dispersion medium is deteriorated, and the applied film cannot be uniformly formed easily. On the other hand, when the metal nanowires 16 have a diameter of less than 20 nm, the metal nanowires 16 tend to have a small length, and the applied film has a high surface resistance. The diameter is further preferably 30 to 150 nm.

For example, a silver nanowire having a predetermined diameter and the like is available from Seashell Technology. Alternatively, the silver nanowire having a predetermined diameter and the like may be prepared in accordance with Liangbing Hu, et al., ACS Nano, vol. 4, no. 5, page 2955 (2010). For example, a copper nanowire having a predetermined diameter and the like may be prepared in accordance with Japanese Patent Application Laid-Open (JP-A) No. 2004-263318 or 2002-266007.

The dispersion medium, in which the metal nanowires 16 are dispersed, is not particularly limited, as long as the medium does not oxidize the metal and can be readily removed by drying. The dispersion medium may be methanol, ethanol, isopropanol, or the like. The concentration of the metal nanowires 16 in the dispersion liquid is not particularly limited and is appropriately selected in view of achieving an excellent dispersion state. The density of the metal nanowires 16 per a unit area of the stacked electrode 10 can be controlled by changing the area and amount of the metal nanowires 16 to be applied.

The very thin metal film may be inserted between the graphene layer and the metal nanowire layer. The metal film is prepared by vacuum deposition of metal or by casting metal nanoparticles or precursor compounds of the metal.

In the case of using a glass substrate as the transparent substrate, it is preferred that a surface of the glass substrate (on which the applied film is to be formed) is subjected to a hydrophilization treatment. For example, the hydrophilization treatment may be a nitrogen plasma treatment. Specifically, in the nitrogen plasma treatment, the glass substrate may be left for 10 minutes in a nitrogen plasma (0.1 millibar) in a magnetron sputtering apparatus (13.56 MHz, 150 W). The applied film can be uniformly formed when the hydrophilicity of a surface of the glass substrate is increased. Alternatively, a surface of a quartz substrate may be treated with 3-aminoethyltriethoxysilane to firmly connect the substrate to the metal nanowires 16.

As shown in FIG. 5, a photoelectric conversion device 50 according to an embodiment has a structure containing two electrodes 52 and 53 and a photoelectric conversion layer 51 interposed therebetween. Among the two electrodes 52 and 53, at least one electrode 53 is the above-described stacked electrode. For example, the photoelectric conversion device 50 can be produced by transferring the stacked electrode onto a solar cell substrate, an organic EL substrate, or the like.

Several specific examples will be described below.

### EXAMPLE 1

A graphene oxide is synthesized in accordance with a literature (W. S. Hummers, et al., J. Am. Chem. Soc., 1958, vol. 80, page 149) using a graphite having an average particle diameter of approximately 4 μm (manufactured by Ito Graphite Co., Ltd.) as a starting material. An ammonia-containing water dispersion liquid of the graphene oxide is dropped and dried on a hydrophilic glass. The graphene oxide is reacted with a hydrated hydrazine vapor at 80° C. for 1 hour in a hydrazine treatment. Thus-obtained graphene plates have an average area of 0.25±0.04 μm². The hydrazine-treated graphene oxide is coated with a dispersion liquid of silver nanowires having an average diameter A of 110±10 nm (manufactured by Seashell Technology) and then dried in an argon flow at 60° C. for 1 hour. The area ratio X of the silver nanowires is 0.30±0.04 in a 4-μm square of the obtained electrode. The B value satisfying the equation (1) is 170±35 nm, the (A+B)² value is 0.079±0.03 μm², and the area of the graphene plates is approximately 3 times larger than (A+B)². The silver nanowires are coated with CYTOP (manufactured by Asahi Glass Co., Ltd.) by using an applicator, the resultant is dried, the above hydrophilic glass is peeled and removed in water, and the residue is dried to obtain a stacked electrode.

The obtained stacked electrode has a surface resistance of 3 Ω/sq. (in the plane direction), a total 550-nm-wavelength light transmittance of 65%, and a total 1500-nm-wavelength light transmittance of 69%.

A 50-nm-thick film of a complex of poly(3,4-ethylenedioxythiophene)/poly(styrenesulfonic acid) (PEDOT/PSS) is applied as a hole injection layer by a spin coating method onto an ITO substrate. A solution of a mixture of an n-type semiconductor of (6,6′)-phenyl-C61-butyric acid methyl ester (PCBM) and a p-type polymer semiconductor of poly(3-hexylthiophene) (P3HT) is applied thereto by a spin coating method to form a photoelectric conversion layer having a thickness of 120 nm. A 10-nm-thick thin film of fine TiO₂ particles is applied as a hole blocking layer thereon. Then, the above stacked electrode is laminate-pressed onto the hole blocking layer under a reduced pressure at 80° C. to obtain an organic thin-film solar cell device. The edges of the layers are sealed by an epoxy resin. Thus-obtained solar cell device exhibits a power generation efficiency of 3.0% or more at the room temperature under a simulated AM1.5 solar light irradiation through the stacked electrode.

### Comparative Example 1

A graphene oxide is synthesized in accordance with a literature (W. S. Hummers, et al., J. Am. Chem. Soc., 1958, vol. 80, page 149) using a graphite having an average particle diameter of approximately 4 μm (manufactured by Ito Graphite Co., Ltd.) as a starting material. The particle size of the graphene oxide is reduced by an ultrasonic treatment. An ammonia-containing water dispersion liquid of the graphene oxide is dropped and dried on a hydrophilic glass. The graphene oxide is reacted with a hydrated hydrazine vapor at 80° C. for 1 hour in a hydrazine treatment. Thus-obtained graphene plates have an average area of 0.04±0.01 μm². The hydrazine-treated graphene oxide is coated with a dispersion liquid of silver nanowires having an average diameter A of 110±10 nm (manufactured by Seashell Technology) and then dried in an argon flow at 60° C. for 1 hour. The area ratio X of the silver nanowires is 0.30±0.04 in a 4-μm square of the obtained electrode. The B value satisfying the equation (1) is 170±35 nm, the (A+B)² value is 0.079±0.03 μm², and the area of the graphene plates is approximately half of (A+B)². The silver nanowires are coated with CYTOP (manufactured by Asahi Glass Co., Ltd.) by using an applicator, the resultant is dried, the above hydrophilic glass is peeled and removed in water, and the residue is dried to obtain a stacked electrode. The obtained stacked electrode has a surface resistance of 3 Ω/sq. (in the plane direction), a total 550-nm-wavelength light transmittance of 65%, and a total 1500-nm-wavelength light transmittance of 69%.

A 50-nm-thick film of a complex of poly(3,4-ethylenedioxythiophene)/poly(styrenesulfonic acid) (PEDOT/PSS) is applied as a hole injection layer by a spin coating method onto an ITO substrate. A solution of a mixture of an n-type semiconductor of (6,6′)-phenyl-C61-butyric acid methyl ester (PCBM) and a p-type polymer semiconductor of poly(3-hexylthiophene) (P3HT) is applied thereto by a spin coating method to form a photoelectric conversion layer having a thickness of 120 nm. A 10-nm-thick thin film of fine TiO₂ particles is applied as a hole blocking layer thereon. Then, the above stacked electrode is laminate-pressed onto the hole blocking layer under a reduced pressure at 80° C. to obtain an organic thin-film solar cell device. The edges of the layers are sealed by an epoxy resin. Thus-obtained solar cell device exhibits a power generation efficiency of ½ or less of that of Example 1 at the room temperature under a simulated AM1.5 solar light irradiation through the stacked electrode. This is because the transparent electrode of Comparative Example 1 has a resistance higher than that of Example 1 in the thickness direction. Furthermore, the solar cell device exhibits a high resistance and a poor electron transfer due to the current-voltage property.

### EXAMPLE 2

An organic thin-film solar cell device is produced in the same manner as Example 1 except that the application amount of the silver nanowires is reduced. The area ratio X of the silver nanowires is 0.1±0.02 in a 4-μm square of the electrode. The B value satisfying the equation (1) is 340±80 nm, the (A+B)² value is 0.20±0.09 μm², and the area of the graphene plates is 0.25±0.04 μm² equal to or slightly larger than (A+B)². The silver nanowires are coated with CYTOP (manufactured by Asahi Glass Co., Ltd.) by using an applicator, the resultant is dried, the hydrophilic glass is peeled and removed in water, and the residue is dried to obtain a stacked electrode.

The obtained stacked electrode has a surface resistance of 50 Ω/sq. (in the plane direction) and a total 550-nm-wavelength light transmittance of 87%. The solar cell device exhibits a power generation efficiency of 3.0% or more at the room temperature under a simulated AM1.5 solar light irradiation through the stacked electrode.

### EXAMPLE 3

A graphene oxide is synthesized in accordance with a literature (W. S. Hummers, et al., J. Am. Chem. Soc., 1958, vol. 80, page 149) using a graphite having an average particle diameter of approximately 4 μm (manufactured by Ito Graphite Co., Ltd.) as a starting material. The particle size of the graphene oxide is reduced by an ultrasonic treatment. An ammonia-containing water dispersion liquid of the graphene oxide is dropped and dried on a hydrophilic glass. The graphene oxide is reacted with a hydrated hydrazine vapor at 80° C. for 1 hour in a hydrazine treatment. Thus-obtained graphene plates have an average area of 0.04±0.01 μm². The hydrazine-treated graphene oxide is coated with a dispersion liquid of silver nanowires having an average diameter A of 60±5 nm (manufactured by Seashell Technology) and then dried in an argon flow at 60° C. for 1 hour. The area ratio X of the silver nanowires is 0.30±0.04 in a 4-μm square of the obtained electrode. The B value satisfying the equation (1) is 94±18 nm, the (A+B)² value is 0.024±0.008 μm², and the area of the graphene plates is approximately 1.7 times larger than (A+B)². The silver nanowires are coated with CYTOP (manufactured by Asahi Glass Co., Ltd.) by using an applicator, the resultant is dried, the above hydrophilic glass is peeled and removed in water, and the residue is dried to obtain a stacked electrode. The obtained stacked electrode has a surface resistance of 15 Ω/sq. (in the plane direction) and a total 550-nm-wavelength light transmittance of 67%.

A 50-nm-thick film of a complex of poly(3,4-ethylenedioxythiophene)/poly(styrenesulfonic acid) (PEDOT/PSS) is applied as a hole injection layer by a spin coating method onto an ITO substrate. A solution of a mixture of an n-type semiconductor of (6,6′)-phenyl-C61-butyric acid methyl ester (PCBM) and a p-type polymer semiconductor of poly(3-hexylthiophene) (P3HT) is applied thereto by a spin coating method to form a photoelectric conversion layer having a thickness of 120 nm. A 10-nm-thick thin film of fine TiO₂ particles is applied as a hole blocking layer thereon. Then, the above stacked electrode is laminate-pressed onto the hole blocking layer under a reduced pressure at 80° C. to obtain an organic thin-film solar cell device. The edges of the layers are sealed by an epoxy resin. Thus-obtained solar cell device exhibits a power generation efficiency of 3.0% or more at the room temperature under a simulated AM1.5 solar light irradiation through the stacked electrode.

### EXAMPLE 4

A single-layer planar graphene, in which carbon atoms are partially substituted by nitrogen atoms, is prepared by a CVD process at 1000° C. for 5 minutes using a mixed reactant gas having ammonia:methane:hydrogen:argon ratio of 15:60:65:200 (ccm) on a catalyst underlayer of a Cu foil. In the CVD process, the graphene is generally prepared in the single-layer form, which may contain a bi- or multi-layer part depending on a preparation condition. The single-layer or multi-layer graphene is treated at 1000° C. for 5 minutes with a mixed flow of ammonia and argon, and then cooled in an argon flow. The surface of the Cu foil is annealed by a laser irradiation heating treatment before the CVD process to increase the crystal grain size. A thermal transfer film is press-bonded to the prepared single-layer or multi-layer graphene, and they are immersed in an ammonia-alkaline cupric chloride etchant to dissolve the Cu. Then, the single-layer or multi-layer graphene is transferred from the thermal transfer film to a PET film. These steps are repeated to stack four single-layer or multi-layer graphene layers on the PET film. Thus-obtained graphene plates have an average area of 0.50±0.04 μm². The graphene layer is coated with a dispersion liquid of silver nanowires having an average diameter A of 110±10 nm (manufactured by Seashell Technology) and then dried in an argon flow at 60° C. for 1 hour. The area ratio X of the silver nanowires is 0.30±0.04 in a 4-μm square of the obtained electrode. The B value satisfying the equation (1) is 170±35 nm, the (A+B)² value is 0.079±0.03 μm², and the area of the graphene plates is larger than (A+B)². The silver nanowires are coated with CYTOP (manufactured by Asahi Glass Co., Ltd.) by using an applicator, the resultant is dried, the above PET film is peeled and removed in water or in ethanol, and the residue is dried to obtain a stacked electrode.

The obtained stacked electrode has a surface resistance of 3 Ω/sq. (in the plane direction), a total 550-nm-wavelength light transmittance of 65%, and a total 1500-nm-wavelength light transmittance of 69%.

A 50-nm-thick film of a complex of poly(3,4-ethylenedioxythiophene)/poly(styrenesulfonic acid) (PEDOT/PSS) is applied as a hole injection layer by a spin coating method onto an ITO substrate. A solution of a mixture of an n-type semiconductor of (6,6′)-phenyl-C61-butyric acid methyl ester (PCBM) and a p-type polymer semiconductor of poly(3-hexylthiophene) (P3HT) is applied thereto by a spin coating method to form a photoelectric conversion layer having a thickness of 120 nm. A 10-nm-thick thin film of fine TiO₂ particles is applied as a hole blocking layer thereon. Then, the above stacked electrode is laminate-pressed onto the hole blocking layer under a reduced pressure at 80° C. to obtain an organic thin-film solar cell device. The edges of the layers are sealed by an epoxy resin. Thus-obtained solar cell device exhibits a power generation efficiency of 3.0% or more at the room temperature under a simulated AM1.5 solar light irradiation through the stacked electrode.

### EXAMPLE 5

An unsubstituted single-layer planar graphene is prepared by a CVD process at 1000° C. for 5 minutes using a mixed reactant gas having a ammonia:methane:hydrogen:argon ratio of 15:60:65:200 (ccm) on a catalyst underlayer of a Cu foil. In the CVD process, the graphene is generally prepared in the single-layer form, which may contain a bi- or multi-layer part depending on a preparation condition. The single-layer or multi-layer graphene is treated at 1000° C. for 5 minutes with an argon mixture flow, and then cooled in an argon flow. The surface of the Cu foil is annealed by a laser irradiation heating treatment before the CVD process to increase the crystal grain size. A thermal transfer film is press-bonded to the prepared single-layer or multi-layer graphene, and they are immersed in an ammonia-alkaline cupric chloride etchant to dissolve the Cu. Then, the single-layer or multi-layer graphene is transferred from the thermal transfer film to a PET film. These steps are repeated to stack four single-layer or multi-layer graphene layers on the PET film. The stack is immersed in a nitric acid solution to perform p-type doping. Thus-obtained graphene plates have an average area of 0.40±0.04 μm². The graphene layer is coated with a dispersion liquid of silver nanowires having an average diameter A of 110±10 nm (manufactured by Seashell Technology) and then dried in an argon flow at 60° C. for 1 hour. The area ratio X of the silver nanowires is 0.30±0.04 in a 4-μm square of the obtained electrode. The B value satisfying the equation (1) is 170±35 nm, the (A+B)² value is 0.079±0.03 μm², and the area of the graphene plates is larger than (A+B)². The silver nanowires are coated with CYTOP (manufactured by Asahi Glass Co., Ltd.) by using an applicator, the resultant is dried, the above PET film is peeled and removed in water or in ethanol, and the residue is dried to obtain a stacked electrode.

The obtained stacked electrode has a surface resistance of 3 Ω/sq. (in the plane direction), a total 550-nm-wavelength light transmittance of 64%, and a total 1500-nm-wavelength light transmittance of 68%.

A 50-nm-thick film of a complex of poly(3,4-ethylenedioxythiophene)/poly(styrenesulfonic acid) (PEDOT/PSS) is applied as a hole injection layer by a spin coating method onto the stacked electrode. A solution of a mixture of an n-type semiconductor of (6,6′)-phenyl-C61-butyric acid methyl ester (PCBM) and a p-type polymer semiconductor of poly(3-hexylthiophene) (P3HT) is applied thereto by a spin coating method to form a photoelectric conversion layer having a thickness of 120 nm. A 10-nm-thick thin film of fine TiO₂ particles is applied as a hole blocking layer thereon. Then, Ca metal is vapor-deposited on the hole blocking layer, and the outer surface and the edges of the layers are sealed by an epoxy resin. Thus-obtained organic thin-film solar cell device exhibits a power generation efficiency of 3.0% or more at the room temperature under a simulated AM1.5 solar light irradiation through the stacked electrode.

### EXAMPLE 6

A graphene oxide is synthesized in accordance with a literature (W. S. Hummers, et al., J. Am. Chem. Soc., 1958, vol. 80, page 149) using a graphite having an average particle diameter of approximately 4 μm (manufactured by Ito Graphite Co., Ltd.) as a starting material. An ammonia-containing water dispersion liquid of the graphene oxide is dropped and dried on a hydrophilic glass. The graphene oxide is reacted with a hydrated hydrazine vapor at 80° C. for 1 hour in a hydrazine treatment. Thus-obtained graphene plates have an average area of 0.25±0.04 μm². A methanol dispersion liquid of copper nanowires having an average diameter of 90±10 nm is used. The copper nanowires are prepared in accordance with JP-A No. 2004-263318. The hydrazine-treated graphene oxide is coated with the copper nanowires and then dried in an argon flow at 60° C. for 1 hour. The area ratio X of the copper nanowires is 0.25±0.04 in a 4-μm square of the obtained electrode. The B value satisfying the equation (1) is 160±40 nm, the (A+B)² value is 0.062±0.025 μm², and the area of the graphene plates is approximately 4 times larger than (A+B)². The copper nanowires are coated with PMMA by using an applicator, the resultant is dried, the above hydrophilic glass is peeled and removed in water, and the residue is dried to obtain a stacked electrode.

The obtained stacked electrode has a surface resistance of 10 Ω/sq. (in the plane direction) and a total 550-nm-wavelength light transmittance of 70%.

A 50-nm-thick film of a complex of poly(3,4-ethylenedioxythiophene)/poly(styrenesulfonic acid) (PEDOT/PSS) is applied as a hole injection layer by a spin coating method onto an ITO substrate. A solution of a mixture of an n-type semiconductor of (6,6′)-phenyl-C61-butyric acid methyl ester (PCBM) and a p-type polymer semiconductor of poly(3-hexylthiophene) (P31-IT) is applied thereto by a spin coating method to form a photoelectric conversion layer having a thickness of 120 nm. A 10-nm-thick thin film of fine TiO₂ particles is applied as a hole blocking layer thereon. Then, the above stacked electrode is laminate-pressed onto the hole blocking layer under a reduced pressure at 80° C. to obtain an organic thin-film solar cell device. The edges of the layers are sealed by an epoxy resin. Thus-obtained solar cell device exhibits a power generation efficiency of 3.0% or more at the room temperature under a simulated AM1.5 solar light irradiation through the stacked electrode.

### EXAMPLE 7

A graphene oxide is synthesized in accordance with a literature (W. S. Hummers, et al., J. Am. Chem. Soc., 1958, vol. 80, page 149) using a graphite having an average particle diameter of approximately 4 μm (manufactured by Ito Graphite Co., Ltd.) as a starting material. An ammonia-containing water dispersion liquid of the graphene oxide is dropped and dried on a hydrophilic glass. The graphene oxide is reacted with a hydrated hydrazine vapor at 80° C. for 1 hour in a hydrazine treatment. Thus-obtained graphene plates have an average area of 0.25±0.04 μm². A water dispersion liquid of gold nanowires having an average diameter of 30±3 nm (manufactured by Sigma-Aldrich) is used. The hydrazine-treated graphene oxide is coated with the gold nanowires and then dried in an argon flow at 150° C. for 1 hour. The area ratio X of the gold nanowires is 0.1±0.02 in a 4-μm square of the obtained electrode. The B value satisfying the equation (1) is 100±25 nm, the (A+B)² value is 0.017±0.007 μm², and the area of the graphene plates is significantly larger than (A+B)². The gold nanowires are coated with PMMA by using an applicator, the resultant is dried, the above hydrophilic glass is peeled and removed in water, and the residue is dried to obtain a stacked electrode.

The obtained stacked electrode has a surface resistance of 20 Ω/sq. (in the plane direction) and a total 550-nm-wavelength light transmittance of 85%.

A 50-nm-thick film of a complex of poly(3,4-ethylenedioxythiophene)/poly(styrenesulfonic acid) (PEDOT/PSS) is applied as a hole injection layer by a spin coating method onto an ITO substrate. A solution of a mixture of an n-type semiconductor of (6,6′)-phenyl-C61-butyric acid methyl ester (PCBM) and a p-type polymer semiconductor of poly(3-hexylthiophene) (P3HT) is applied thereto by a spin coating method to form a photoelectric conversion layer having a thickness of 120 nm. A 10-nm-thick thin film of fine TiO₂ particles is applied as a hole blocking layer thereon. Then, the above stacked electrode is laminate-pressed onto the hole blocking layer under a reduced pressure at 80° C. to obtain an organic thin-film solar cell device. The edges of the layers are sealed by an epoxy resin. Thus-obtained solar cell device exhibits a power generation efficiency of 3.0% or more at the room temperature under a simulated AM1.5 solar light irradiation through the stacked electrode.

### EXAMPLE 8

A graphene oxide is synthesized in accordance with a literature (W. S. Hummers, et al., J. Am. Chem. Soc., 1958, vol. 80, page 149) using a graphite having an average particle diameter of approximately 4 μm (manufactured by Ito Graphite Co., Ltd.) as a starting material. An ammonia-containing water dispersion liquid of the graphene oxide is dropped and dried on a hydrophilic glass. The graphene oxide is reacted with a hydrated hydrazine vapor at 80° C. for 1 hour in a hydrazine treatment. Thus-obtained graphene plates have an average area of 0.25±0.04 μm². The hydrazine-treated graphene oxide is coated with a dispersion liquid of silver nanowires having an average diameter A of 110±10 nm (manufactured by Seashell Technology) and then dried in an argon flow at 60° C. for 1 hour. The area ratio X of the silver nanowires is 0.30±0.04 in a 4-μm square of the obtained electrode. The B value satisfying the equation (1) is 170±35 nm, the (A+B)² value is 0.079±0.03 μm², and the area of the graphene plates is approximately 3 times larger than (A+B)². The silver nanowires are coated with PMMA by using an applicator, the resultant is dried, the above hydrophilic glass is peeled and removed in water, and the residue is dried to obtain a stacked electrode.

The obtained stacked electrode has a surface resistance of 3 Ω/sq. (in the plane direction) and a total 550-nm-wavelength light transmittance of 65%.

A 50-nm-thick film of a complex of poly(3,4-ethylenedioxythiophene)/poly(styrenesulfonic acid) (PEDOT/PSS) is applied as a hole injection layer by a spin coating method onto an ITO electrode formed on a PET film. A p-type organic semiconductor of N,N′-di-1-naphthyl-N,N′-diphenyl-1,1′-biphenyl-4,4′-diamine (NPD) is vapor-deposited into a thickness of 30 nm on the hole injection layer, tris(8-hydroxyquinoline) aluminum (Alq₃) capable of acting as an n-type semiconductor for transferring electrons and of emitting a light is further vapor-deposited into a thickness of 40 nm thereon, and LiF is further vapor-deposited into a thickness of 1.5 nm as an electron injection layer thereon.

Then, the above stacked electrode is laminate-pressed onto the electron injection layer under a reduced pressure at 80° C. to obtain an organic EL device. The edges of the layers are sealed by an epoxy resin.

Furthermore, a roughened surface film is attached to either electrode to improve the light output efficiency.

Thus-obtained organic EL device is transparent, is capable of both-side light emission, has a high light emission efficiency, and is lightweight and flexible.

### Comparative Example 2

A graphene oxide is synthesized in accordance with a literature (W. S. Hummers, et al., J. Am. Chem. Soc., 1958, vol. 80, page 149) using a graphite having an average particle diameter of approximately 4 μm (manufactured by Ito Graphite Co., Ltd.) as a starting material. The particle size of the graphene oxide is reduced by an ultrasonic treatment. An ammonia-containing water dispersion liquid of the graphene oxide is dropped and dried on a hydrophilic glass. The graphene oxide is reacted with a hydrated hydrazine vapor at 80° C. for 1 hour in a hydrazine treatment. Thus-obtained graphene plates have an average area of 0.04±0.01 μm². The hydrazine-treated graphene oxide is coated with a dispersion liquid of silver nanowires having an average diameter A of 110±10 nm (manufactured by Seashell Technology) and then dried in an argon flow at 60° C. for 1 hour. The area ratio X of the silver nanowires is 0.30±0.04 in a 4-μm square of the obtained electrode. The B value satisfying the equation (1) is 170±35 nm, the (A+B)² value is 0.079±0.03 μm², and the area of the graphene plates is approximately half of (A+B)². The silver nanowires are coated with PMMA by using an applicator, the resultant is dried, the above hydrophilic glass is peeled and removed in water, and the residue is dried to obtain a stacked electrode. The obtained stacked electrode has a surface resistance of 3 Ω/sq. (in the plane direction) and a total 550-nm-wavelength light transmittance of 65%.

A 50-nm-thick film of a complex of poly(3,4-ethylenedioxythiophene)/poly(styrenesulfonic acid) (PEDOT/PSS) is applied as a hole injection layer by a spin coating method onto an ITO electrode formed on a PET film. A p-type organic semiconductor of N,N′-di-1-naphthyl-N,N′-diphenyl-1,1′-biphenyl-4,4′-diamine (NPD) is vapor-deposited into a thickness of 30 nm on the hole injection layer, tris(8-hydroxyquinoline) aluminum (Alq₃) capable of acting as an n-type semiconductor for transferring electrons and of emitting a light is further vapor-deposited into a thickness of 40 nm thereon, and LiF is further vapor-deposited into a thickness of 1.5 nm as an electron injection layer thereon.

Then, the above stacked electrode is laminate-pressed onto the electron injection layer under a reduced pressure at 80° C. to obtain an organic EL device. The edges of the layers are sealed by an epoxy resin.

Furthermore, a roughened surface film is attached to either electrode to improve the light output efficiency.

Thus-obtained organic EL device is transparent, capable of both-side light emission, and lightweight and flexible. However, the light emission efficiency of the organic EL device is approximately 60% of that of Example 8. This is because the transparent electrode of Comparative Example 2 has a resistance higher than that of Example 8 in the thickness direction. Furthermore, the organic EL device exhibits a high resistance and a poor electron transfer due to the current-voltage property.

### EXAMPLE 9

Molybdenum is vapor-deposited on a stainless steel (SUS304) foil. A photoelectric conversion layer of a Cu—Ga film, an In film, a p-type selenide CIGS film, an n-type CdS film, and a ZnO film are formed in this order thereon.

Then, the stacked electrode produced in Example 1 is laminate-pressed onto the ZnO film under a reduced pressure at 80° C. to obtain a compound thin-film solar cell device. The edges of the layers are sealed by an epoxy resin.

The solar cell device of the embodiment has a high energy conversion efficiency, can be relatively easily prevented from being deteriorated in the output by using only a simple sealant without water removing agents and oxygen removing agents, and is lightweight and flexible.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A stacked electrode comprising:
a multi-layered graphene film and
a metal wiring formed thereon, wherein
the metal wiring contains randomly oriented metal nanowires,
the multi-layered graphene film contains a laminate of graphene sheets,
the graphene sheets each contain an aggregate of graphene plates, and
the graphene plates have an average area of (A+B)² nm² or more, wherein A (nm) represents the average diameter of the metal nanowires, B (nm) satisfies the equation (1) of B²/(A+B)²=(1−X), and X represents the ratio of the area of the metal nanowires projected in a stacking direction of the stacked electrode.

2. The stacked electrode according to claim 1, wherein the graphene plates have an average area of 2(A+B)² nm² or more.

3. The stacked electrode according to claim 1, wherein the graphene plates have an average area of 3(A+B)² nm² or more.

4. The stacked electrode according to claim 1, wherein the metal nanowires have an average diameter of 30 to 150 nm.

5. The stacked electrode according to claim 1, wherein the metal nanowires contain silver, gold, or copper.

6. The stacked electrode according to claim 1, wherein the multi-layered graphene film has a thickness of 5 nm or less.

7. The stacked electrode according to claim 1, coated with a near-infrared transparent resin.

8. The stacked electrode according to claim 1, wherein carbon atoms in the multi-layered graphene film are partially substituted by nitrogen or boron atoms.

9. A method for producing a stacked electrode comprising:
preparing a multi-layered graphene film;
applying a dispersion liquid of a metal nanowire onto the multi-layered graphene film, and
removing a solvent from the applied dispersion liquid.

10. The method for producing a stacked electrode according to claim 9, wherein the method comprises preparing a transparent polymer layer onto the metal nanowire.

11. The method for producing a stacked electrode according to claim 10, wherein the method comprises preparing a multi-layered graphene film on a substrate, and comprises peeling the multi-layered graphene, the metal nanowire and the transparent polymer as a conducting film from the substrate.

12. A photoelectric conversion device comprising at least two electrodes and a photoelectric conversion layer interposed therebetween, wherein
at least one of the electrodes is a stacked electrode containing a multi-layered graphene film and a metal wiring formed thereon,
the metal wiring contains randomly oriented metal nanowires,
the multi-layered graphene film contains a laminate of graphene sheets,
the graphene sheets each contain an aggregate of graphene plates, and
the graphene plates have an average area of (A+B)² nm² or more, wherein A (nm) represents the average diameter of the metal nanowires, B (nm) satisfies the equation (1) of B²/(A+B)²=(1−X), and X represents the ratio of the area of the metal nanowires projected in the stacking direction of the stacked electrode.

13. The photoelectric conversion device according to claim 12, wherein the graphene plates have an average area of 2(A+B)² nm² or more.

14. The photoelectric conversion device according to claim 12, wherein the graphene plates have an average area of 3(A+B)² nm² or more.
